(19) United States
(12) Patent Application Publication
(10) Pub. No.: US 2016/0079403 A1
(43) Pub. Date: Mar. 17, 2016

(54) FIELD EFFECT TRANSISTOR

(71) Applicant: Kabushiki Kaisha Toshiba, Minato-ku (JP)

(72) Inventor: Takuji YAMAMURA, Kawasaki (JP)

(73) Assignee: Kabushiki Kaisha Toshiba, Minato-ku (JP)

(21) Appl. No.: 14/729,573

(22) Filed: Jun. 3, 2015

(30) Foreign Application Priority Data
Sep. 12, 2014 (JP) 2014-186932

(51) Int. Cl. H01L 29/778; H01L 29/40; H01L 29/423

(52) U.S. Cl. CPC H01L 29/778; H01L 29/42316; H01L 29/402

(57) ABSTRACT

A field effect transistor includes a multilayer body, a finger source electrode, a finger drain electrode, a finger gate electrode, an insulating layer, and a source field plate. A finger gate electrode includes a bottom part. The bottom part has a first side surface and a second side surface. A source field plate includes a finger part and an interconnect part. A side surface of the finger part is provided between the second side surface of the finger gate electrode and the finger drain electrode. A source terminal electrode covers the finger source electrode and a tip part of the interconnect part. A side surface of the finger source electrode has an opening recessed from the first side surface. And the tip part is extended to a part of the insulating layer exposed in the opening.

### CROSS-REFERENCE TO RELATED APPLICATIONS

This application is based upon and claims the benefit of priority from Japanese Patent Application No. 2014-186932, filed on Sep. 12, 2014; the entire contents of which are incorporated herein by reference.

### FIELD

Embodiments described herein relate generally a field effect transistor.

### BACKGROUND

A field effect transistor having a heterojunction can easily operate at high voltage and high temperature above the microwave band. The field effect transistor is applicable to e.g. microwave communication equipment and radar devices.

In the field effect transistor, a source field plate can be provided between the finger gate electrode and the finger drain electrode. Then, the gate-drain capacitance is reduced by the electromagnetic shield effect. This can enhance the maximum stable gain.

In the source field plate, if the width of the interconnect part connected to the finger source electrode is wide, the gate-source capacitance increases and the microwave characteristics is degraded. On the other hand, if the width of the interconnect part is too narrow, step disconnection is likely to occur. This increases the variation of the microwave characteristics and decreases the production yield.

30

### BRIEF DESCRIPTION OF THE DRAWINGS

FIG. 1A is a partial schematic plan view of a field effect transistor according to a first embodiment, and FIG. 1B is a schematic sectional view taken along line A-A;

FIG. 2 is a partial schematic plan view of a field effect transistor according to a variation of the first embodiment;

FIG. 3A is a partial schematic plan view of a field effect transistor according to a comparative example, and FIG. 3B is a schematic sectional view taken along line B-B;

FIG. 4A is a partial schematic plan view of a field effect transistor according to a second embodiment, and FIG. 4B is a schematic sectional view taken along line C-C;

FIG. 5A is a graph showing the dependence of gate-source capacitance on the source field plate length, FIG. 5B is a graph showing the dependence of gate-drain capacitance on the source field plate length, and FIG. 5C is a graph showing the dependence of drain-source capacitance on the source field plate length; and

FIG. 6 is a graph showing the dependence of power-added efficiency on output power.

### DETAILED DESCRIPTION

In general, according to one embodiment, a field effect transistor includes a multilayer body, a finger source electrode, a finger drain electrode, a finger gate electrode, an insulating layer, and a source field plate. A multilayer body is made of semiconductor and has a heterojunction generating a two-dimensional electron gas layer. A finger source electrode is provided on a front surface of the multilayer body. A finger drain electrode is provided parallel to the finger source electrode on the front surface of the multilayer body. A finger gate electrode includes a bottom part provided on the front surface of the multilayer body. The bottom part has a first side surface facing the finger source electrode in parallel and a second side surface facing the finger drain electrode in parallel. An insulating layer covers the front surface of the multilayer body between the finger gate electrode and the finger source electrode, the front surface of the multilayer body between the finger gate electrode and the finger drain electrode, and the finger gate electrode. A source field plate is provided on an upper surface of the insulating layer and includes a finger part parallel to the finger gate electrode and an interconnect part connected to the finger source electrode. The finger part covers the second side surface via the insulating layer. A side surface of the finger part facing the finger drain electrode is provided between the second side surface of the finger gate electrode and the finger drain electrode. A source terminal electrode covers the finger source electrode and a tip part of the interconnect part. A side surface of the finger source electrode facing the first side surface of the finger gate electrode has an opening recessed from the first side surface. And the tip part is extended to a part of the insulating layer exposed in the opening.

Embodiments of the invention will now be described with reference to the drawings.

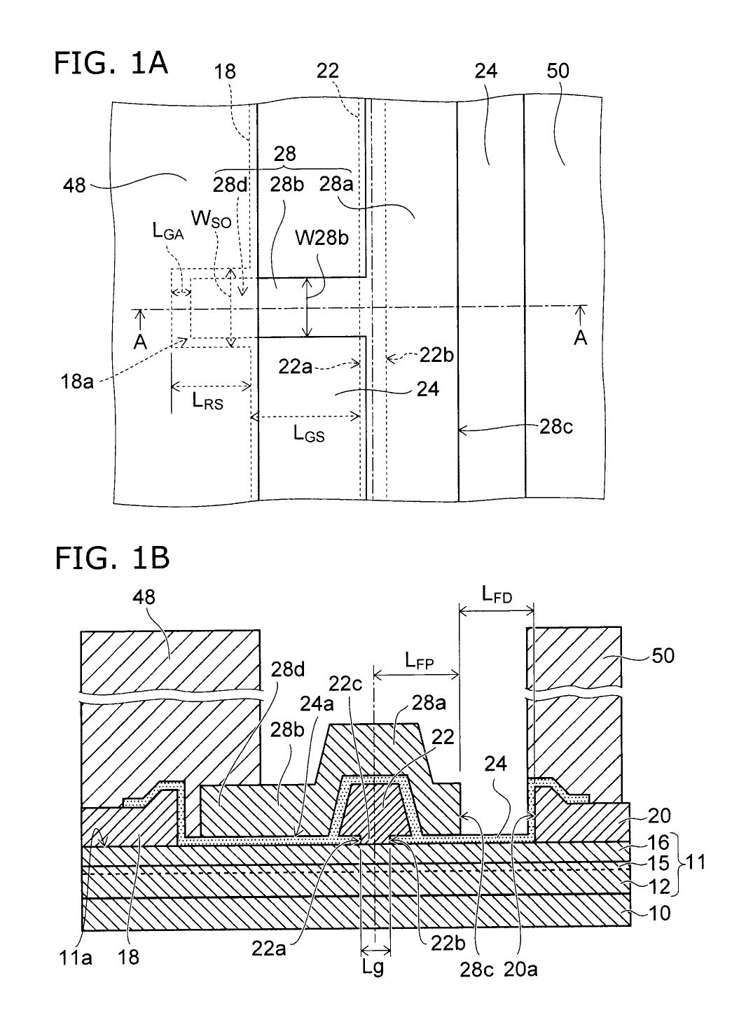

FIG. 1A is a partial schematic plan view of a field effect transistor according to a first embodiment. FIG. 1B is a schematic sectional view taken along line A-A.

In the first embodiment, the field effect transistor is a HEMT (high electron mobility transistor). However, the invention is not limited thereto. The field effect transistor may be a MESFET (metal semiconductor field effect transistor) or the like.

The field effect transistor includes a multilayer body 11 made of semiconductor, a finger source electrode 18, a finger drain electrode 20, a finger gate electrode 22, an insulating layer 24, a source field plate 28, and a source terminal electrode 48.

The multilayer body 11 has a heterojunction made of an electron supply layer 16 and a channel layer 12. Electrons moved from the electron supply layer 16 to the channel layer 12 generate a two-dimensional electron gas (2 DEG) layer 15. This constitutes an electron gas with high mobility and high density. The multilayer body 11 can be made of a nitride-based material represented by InₓGa_{y}Al_{1-x-y}N (0≦x≦1, 0≦y≦1, x+y≦1). In this case, for instance, the electron supply layer 16 can be made of Al_{0.2}Ga_{0.8}N, and the channel layer 12 can be made of GaN. The multilayer body 11 can be formed by providing a buffer layer on a substrate 10, and stacking a channel layer 12 and an electron supply layer 16 in this order on the buffer layer.

For instance, the thickness of the electron supply layer 16 can be set to 5-100 nm. The thickness of the channel layer 12 can be set to 3-20 nm. The electron supply layer 16 and the channel layer 12 may be non-doped. Alternatively, the multilayer body 11 can be made of an AlGaAs-based material.

The finger source electrode 18 is provided on the front surface 11a of the multilayer body 11. The finger drain electrode 20 is provided parallel to the finger source electrode 18 on the front surface 11a of the multilayer body 11. The finger gate electrode 22 has a first side surface 22a facing the finger source electrode 18 in parallel, and a second side surface 22b facing the finger drain electrode 20 in parallel. The multilayer body 11 and the finger source electrode 18, the finger drain electrode 20, and the finger gate electrode 22 provided on the front surface 11a of the multilayer body 11 constitute a cell region of the field effect transistor. A plurality of cell regions can be arranged to constitute a high-power field effect transistor.

The finger gate electrode 22 includes a bottom part 22c provided on the front surface 11a of the multilayer body 11. The bottom part 22c of the finger gate electrode 22 has a first side surface 22a facing the finger source electrode 18 in parallel, and a second side surface 22b facing the finger drain electrode 20 in parallel. The finger gate electrode 22 constitutes a Schottky barrier including Ni provided on the surface of the electron supply layer 16. The finger gate electrode 22 further includes e.g. Au on Ni. The thickness of the finger gate electrode 22 is set to e.g. 500 nm. The gate length Lg of the finger gate electrode 22 can be set to e.g. 0.2-1 μm.

The finger source electrode 18 and the finger drain electrode 20 are formed by stacking e.g. TiAl/Ti/Pt from the front surface 11a side of the multilayer body 11. The thickness of the finger source electrode 18 and the finger drain electrode 20 can be set to e.g. 400 nm. Then, the contact resistance is e.g. 0.25 Ω·mm. Thus, an ohmic contact can be obtained.

The insulating layer 24 covers the front surface 11a of the multilayer body 11 between the finger gate electrode 22 and the finger source electrode 18, the front surface 11a of the multilayer body 11 between the finger gate electrode 22 and the finger drain electrode 20, and the finger gate electrode 22. In the case where the multilayer body 11 is made of a nitride-based material, the operating current range may be narrowed by current collapse in large-signal operation. This may make it difficult to achieve high-power operation. It is preferable to cover the front surface 11a of the multilayer body 11 with SiN, because it can suppress current collapse. The thickness of SiN is set to e.g. 50 nm.

The source field plate 28 includes a finger part 28a parallel to the finger gate electrode 22, and an interconnect part 28b connected to the finger source electrode 18. The source field plate 28 is provided on the upper surface 24a of the insulating layer 24. Of the side surfaces of the finger part 28a of the source field plate 28, the side surface 28c facing the side surface 20a of the finger drain electrode 20 is provided between the second side surface 22b of the finger gate electrode 22 and the finger drain electrode 20. The spacing L_{FD} between the side surface 28c and the side surface 20a of the finger drain electrode 20 can be set to e.g. 1-10 μM. The width W28 of the interconnect part 28b can be set to e.g. 1-3 μm. The spacing L_{FP} is defined as a distance between a center of the finger gate electrode 22 and the side surface of the field part 28a.

The source field plate 28 is a multilayer of e.g. Ti/Pt/Au. The thickness of the source field plate 28 is set to e.g. 500 nm. As shown in FIG. 1B, the side surface of the upper part of the finger gate electrode 22 can be tapered. This can suppress step disconnection between the finger part 28a and the interconnect part 28b of the source field plate 28.

The second side surface 22b can be covered from above with the finger part 28a of the source field plate 28. This can relax electric field concentration occurring near the crossing region of the second side surface 22b and the front surface 11a of the multilayer body 11. Thus, the breakdown voltage can be increased. This facilitates application of large-signal microwave voltage to achieve high-power operation.

The source terminal electrode 48 is connected to the finger source electrode 18 and the interconnect part 28b of the source field plate 28. The finger source electrode 18 facing the first side surface 22a of the finger gate electrode 22 includes an opening 18a recessed from the first side surface 22a. The tip part 28d of the interconnect part 28b is extended inside the opening 18a. The tip part 28d covers part of the insulating layer 24 exposed inside. The spacing L_{GA} between the tip part 28d of the interconnect part 28b and the recessed opening 18a is set to e.g. 0.5 μm. The spacing L_{AS} between the first side surface 22a and the finger source electrode 18 is set to e.g. 1-3 μm.

The tip part 28d of the interconnect part 28b and the finger source electrode 18 are covered with and connected to the source terminal electrode 48. The source terminal electrode 48 on the finger source electrode 18 and the drain terminal electrode 50 on the finger drain electrode 20 include Ni and Au. The thickness of the source terminal electrode 48 and the drain terminal electrode 50 is set to e.g. several The source terminal electrode 48 and the drain terminal electrode 50 can be formed by plating or evaporation.

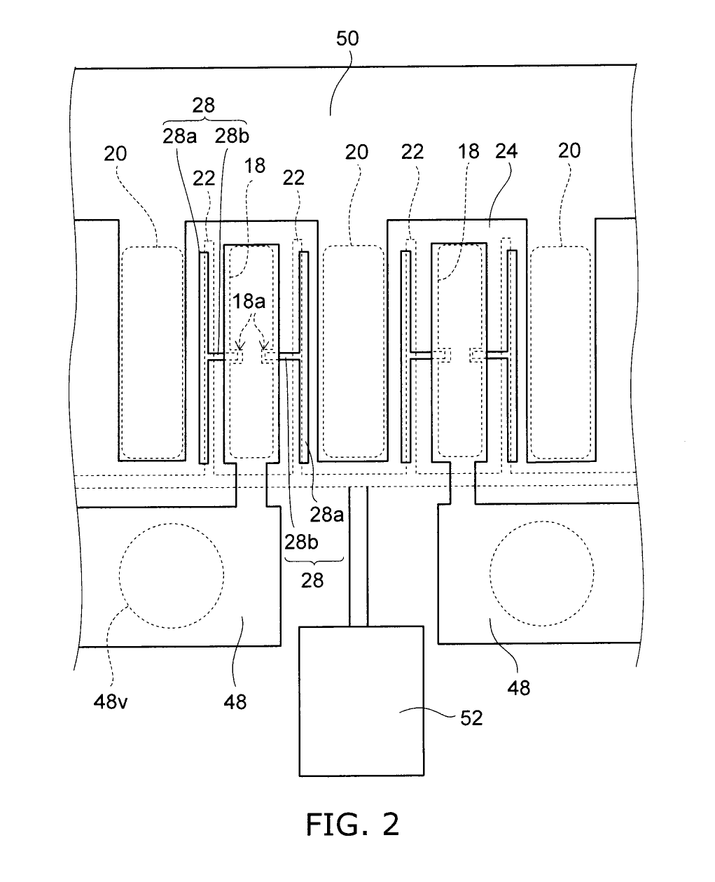

FIG. 2 is a partial schematic plan view of a field effect transistor according to a variation of the first embodiment.

The finger source electrode 18 is sandwiched between two finger gate electrodes 22. The finger source electrode 18 includes at least two openings 18a recessed from the respective finger gate electrodes 22. A plurality of finger source electrodes 18 are bundled and connected to a gate terminal electrode 52. A plurality of finger drain electrodes 20 are bundled and connected to a drain terminal electrode 50.

In the first embodiment and the variation associated therewith, the opening 18a is provided near the central part of the finger source electrode. However, the position of the opening 18a is not limited thereto.

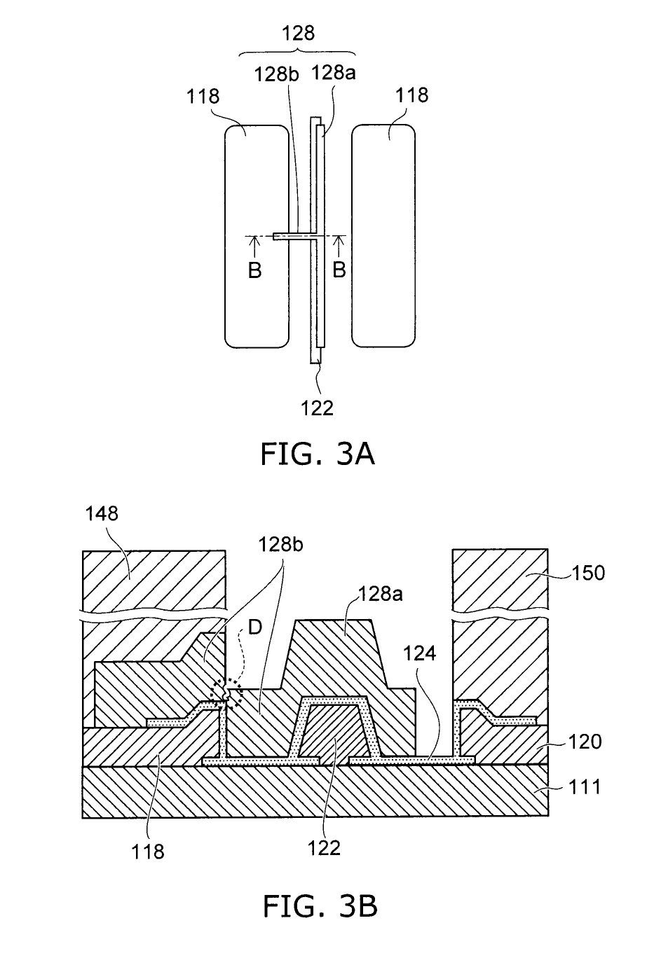

FIG. 3A is a partial schematic plan view of a field effect transistor according to a comparative example. FIG. 3B is a schematic sectional view taken along line B-B.

In the comparative example, the tip part of the interconnect part 128b of the source field plate 128 is provided on the finger source electrode 118, which is a contact layer. If the finger source electrode 118 is thick and the interconnect part 128b is thin, step disconnection D is likely to occur. The source field plate 128 placed in the floating state by the step disconnection D is undesirable, because it decreases the gate-source breakdown voltage and the gate-drain breakdown voltage.

If the finger source electrode 118 is thinned, the source contact resistance is increased. On the other hand, if the interconnect part 128b is thickened, the width processing accuracy of the source field plate 128 is decreased. This is undesirable, because it increases the variation of microwave characteristics, and incurs cost increase due to the decrease of production yield.

In contrast, in the first embodiment, no contact metal layer is provided on the finger source electrode 18. This reduces step difference between the finger source electrode 18 and the interconnect part 128b, and suppresses step disconnection. Furthermore, the opening 18a recessed from the finger gate electrode 22 is provided in the finger source electrode 18.

The length of the opening 18a in the direction along the interconnect part 28b is denoted by L_{RS}. If the length L_{RS} is made longer, the source terminal electrode 48 can be in reliable contact with the finger source electrode 18 and the interconnect part 28b while maintaining a short source-gate distance L_{GS} in the region in which electrons travel. Thus, high yield can be achieved while maintaining uniform microwave characteristics. This enhances mass productivity.

For instance, the width of the finger source electrode 18 in the direction along the interconnect part 28b is 15 μm. Then, the length L_{RS} of the opening 18a can be set to e.g. 5 μm. If the width W28b of the interconnect part 28b is set to e.g. 2 μm, the gate-drain capacitance Cgd can be reduced while suppressing the increase of gate-source capacitance. The W_{SO} of the opening 18a is set to e.g. 3-5 μm.

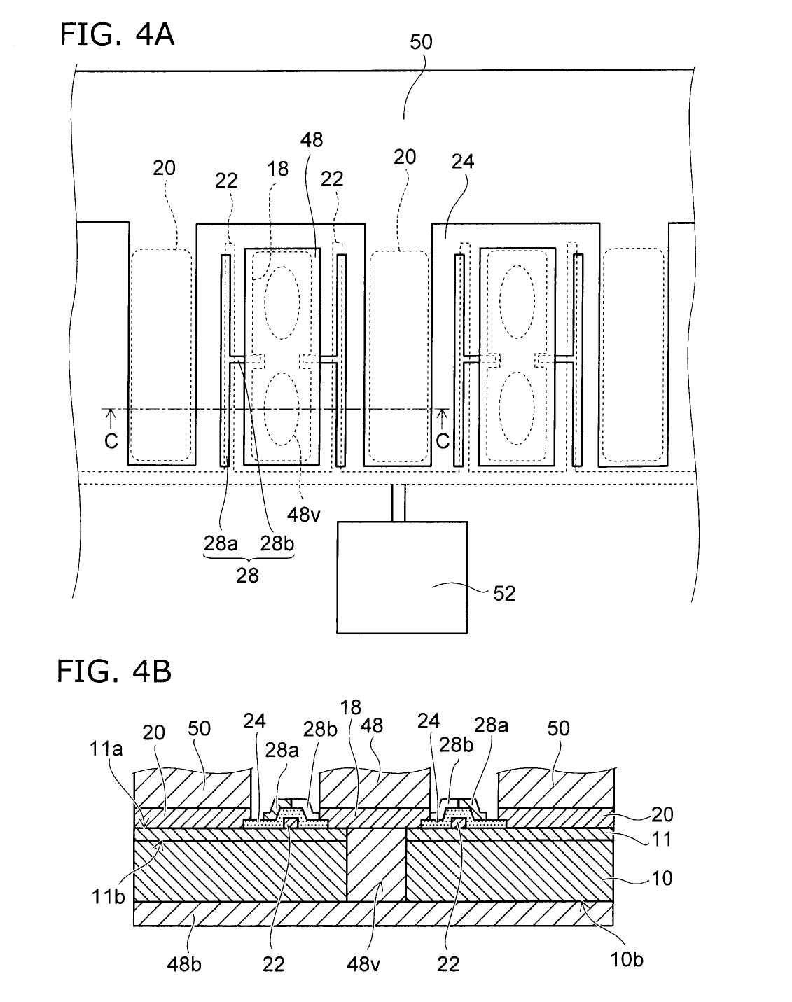

FIG. 4A is a partial schematic plan view of a field effect transistor according to a second embodiment. FIG. 4B is a schematic sectional view taken along line C-C.

The field effect transistor includes a multilayer body 11 made of semiconductor, a finger source electrode 18, a finger drain electrode 20, a finger gate electrode 22, an insulating layer 24, a source field plate 28, a drain terminal electrode 50, a source terminal electrode 48, and a substrate 10. The substrate 10 is provided on the back surface 11b side of the multilayer body 11, and has an insulating property.

The source terminal electrode 48 includes a conductor part 48v and a back surface region 48b. The conductor part 48v is embedded in a through hole extending from the front surface 11a of the multilayer body 11 to the back surface 10b of the substrate 10. The conductor part 48v is connected to a region in the planar region of the finger source electrode 18. The conductor part includes two regions provided along the first side face of the finger gate electrode. And a narrow region of the finger source electrode due to the opening and the two region of the conductor part do not overlap in plan view. For instance, the long diameter of the through hole is set to 50. The short diameter of the through hole is set to 30. The thickness of the substrate 10 is set to e.g. 30-100 μm.

In the second embodiment, no source terminal electrode for wire bonding is provided on the front surface 11a of the multilayer body 11. Thus, assembly is easy, and the chip size can be reduced. This further enhances mass productivity.

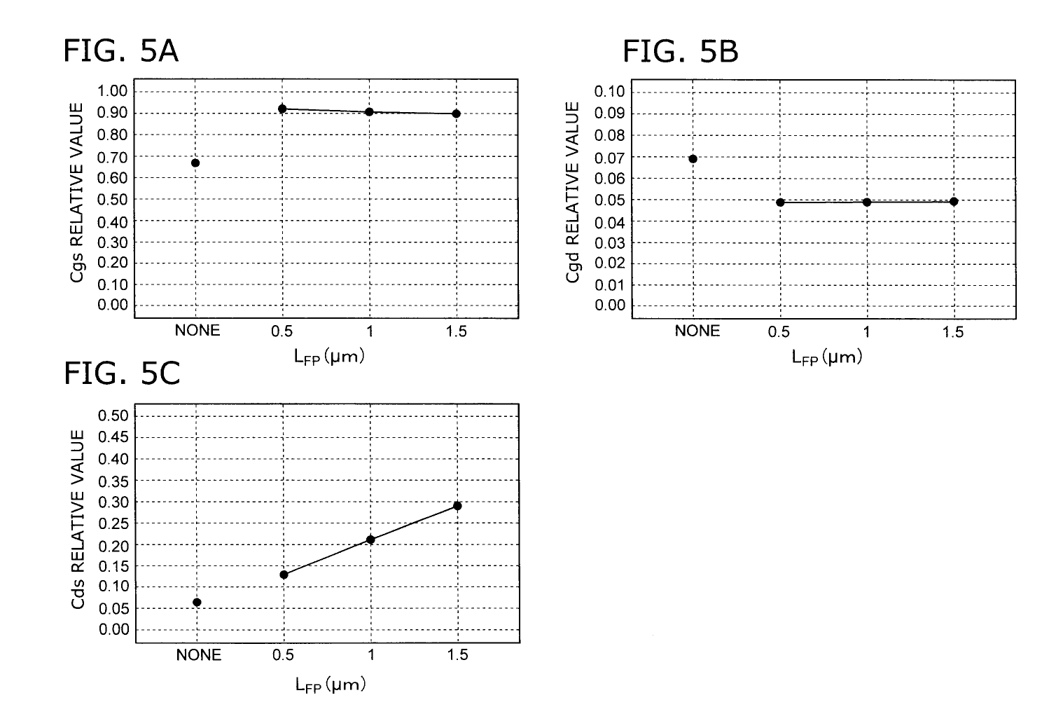

FIG. 5A is a graph showing the dependence of gate-source capacitance on the source field plate length. FIG. 5B is a graph showing the dependence of gate-drain capacitance on the source field plate length. FIG. 5C is a graph showing the dependence of drain-source capacitance on the source field plate length.

The vertical axis represents the relative value of capacitance. The horizontal axis represents the source field plate length L_{FP} (μm). The source field plate length L_{FP} is varied as none (no source field plate), 0.5 μm, 1.0 μm, and 1.5 μm.

As shown in FIG. 5A, the gate-source capacitance Cgs was increased by generally 34% when the source field plate 28 was provided. However, the variation rate of the gate-source capacitance Cgs was as small as 2% or less when the source field plate length L_{FP} was 0.5-1.5 μm. Here, an excessively large gate-source capacitance Cgs is undesirable because it degrades the microwave frequency characteristics. In this embodiment, the increase of gate-source capacitance Cgs is suppressed by narrowing the width W28b of the interconnect part 28b to e.g. 2 μm.

As shown in FIG. 5B, the gate-drain capacitance Cgd was decreased by generally 29% when the source field plate 28 was provided. The variation rate thereof was as small as 1% or less when the source field plate length L_{FP} was 0.5-1.5 μm. That is, the gate-drain capacitance Cgd was successfully reduced to generally 71% by the shield effect of the source field plate 28. This reduces the amount of feedback between the gate terminal electrode 52 and the drain terminal electrode 50. Thus, the gain such as maximum stable gain MSG can be increased.

As shown in FIG. 5C, the relative value of the drain-source capacitance Cds was 0.13 when the source field plate length L_{FP} was 0.5 μm. The relative value of the drain-source capacitance Cds was 0.21 when the source field plate length L_{FP} was 1.0 μm. Furthermore, the relative value of the drain-source capacitance Cds was 0.29 when the source field plate length L_{FP} was 1.5 μm. This relative value was generally five times the relative value 0.06 for no source field plate. That is, the drain-source capacitance Cds was increased generally in proportion to the source field plate length L_{FP}. Thus, the source field plate length L_{FP} is preferably 1.5 μm or less.

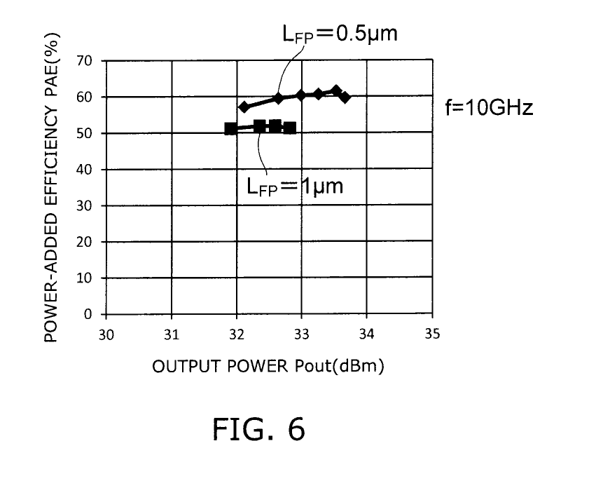

FIG. 6 is a graph showing the dependence of power-added efficiency on output power.

The measurement frequency was 10 GHz. The drain-source voltage Vds was 24 V. The vertical axis represents the power-added efficiency (%). The horizontal axis represents the output power (dBm). At an output power of 32.5 dBm, the power-added efficiency PAE was 60% when the source field plate length L_{FP} was 0.5 μm. In contrast, the power-added efficiency was 51% when the source field plate length L_{FP} was 1 μm. Thus, the power-added efficiency was made lower by 9% than that for a source field plate length L_{FP} of 0.5 μm. μ

In the second embodiment, by decreasing the source field plate length L_{FP}, the drain-source capacitance Cds can be reduced while maintaining a low gate-drain capacitance Cgd. Furthermore, this can reduce the radio frequency current flowing in the drain-source capacitance Cds. As a result, the power consumed uselessly in the drain resistance is further reduced. This can further enhance the power-added efficiency. That is, the source field plate length L_{FP} is more preferably 1 μm or less.

The first and second embodiments provide a field effect transistor having uniform radio frequency characteristics and high mass productivity. Such a field effect transistor can be widely used in microwave communication equipment and radar devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A field effect transistor comprising:
a multilayer body made of semiconductor and having a heterojunction generating a two-dimensional electron gas layer;
a finger source electrode provided on a front surface of the multilayer body;
a finger drain electrode provided parallel to the finger source electrode on the front surface of the multilayer body;
a finger gate electrode including a bottom part provided on the front surface of the multilayer body, the bottom part having a first side surface facing the finger source electrode in parallel and a second side surface facing the finger drain electrode in parallel;
an insulating layer covering the front surface of the multilayer body between the finger gate electrode and the finger source electrode, the front surface of the multilayer body between the finger gate electrode and the finger drain electrode, and the finger gate electrode;
a source field plate provided on an upper surface of the insulating layer and including a finger part parallel to the finger gate electrode and an interconnect part connected to the finger source electrode, the finger part covering the second side surface via the insulating layer, and a side surface of the finger part facing the finger drain electrode being provided between the second side surface of the finger gate electrode and the finger drain electrode; and
a source terminal electrode covering the finger source electrode and a tip part of the interconnect part,
a side surface of the finger source electrode facing the first side surface of the finger gate electrode having an opening recessed from the first side surface, and
the tip part being extended to a part of the insulating layer exposed in the opening.

2. The transistor according to claim 1, further comprising:
a substrate provided on a back surface side of the multilayer body and having an insulating property,
the source terminal electrode including a conductor part embedded in a through hole extending from the front surface of the multilayer body to a back surface of the substrate.

3. The transistor according to claim 2, wherein the conductor part includes two regions provided along the first side surface of the finger gate electrode, and
a narrow region of the finger source electrode due to the opening and the two region of the conductor part do not overlap in plan view.

4. The transistor according to claim 1, wherein the finger part and the interconnect part are orthogonal.

5. The transistor according to claim 3, wherein the finger part and the interconnect part are orthogonal.

6. The transistor according to claim 1, wherein the finger source electrode is sandwiched between two finger gate electrodes, and includes at least two openings recessed from the two finger gate electrodes, respectively.

7. The transistor according to claim 3, wherein the finger source electrode is sandwiched between two finger gate electrodes, and includes at least two openings recessed from the two finger gate electrodes, respectively.

8. The transistor according to claim 5, wherein the finger source electrode is sandwiched between two finger gate electrodes, and includes at least two openings recessed from the two finger gate electrodes, respectively.

9. The transistor according to claim 1, wherein the spacing between a center of the finger gate electrode and the side surface of the finger part facing the finger drain electrode is not more than 1 μm.

10. A field effect transistor comprising:
a multilayer body including InₓGa_{y}Al_{1-x-y}N (0≦x≦1, 0≦y≦1, x+y≦1) and having a heterojunction generating a two-dimensional electron gas layer;
a finger source electrode provided on a front surface of the multilayer body;
a finger drain electrode provided parallel to the finger source electrode on the front surface of the multilayer body;
a finger gate electrode including a bottom part provided on the front surface of the multilayer body, the bottom part having a first side surface facing the finger source electrode in parallel and a second side surface facing the finger drain electrode in parallel;
an insulating layer covering the front surface of the multilayer body between the finger gate electrode and the finger source electrode, the front surface of the multilayer body between the finger gate electrode and the finger drain electrode, and the finger gate electrode;
a source field plate provided on an upper surface of the insulating layer and including a finger part parallel to the finger gate electrode and an interconnect part connected to the finger source electrode, the finger part covering the second side surface via the insulating layer, and a side surface of the finger part facing the finger drain electrode in parallel being provided between the second side surface of the finger gate electrode and the finger drain electrode; and
a source terminal electrode covering the finger source electrode and a tip part of the interconnect part,
a side surface of the finger source electrode opposed to the first side surface of the finger gate electrode having an opening recessed from the first side surface, and
the tip part being extended to a part of the insulating layer exposed in the opening.

11. The transistor according to claim 10, further comprising:
a substrate provided on a back surface side of the multilayer body and having an insulating property,
the source terminal electrode including a conductor part embedded in a through hole extending from the front surface of the multilayer body to a back surface of the substrate.

12. The transistor according to claim 11, wherein the conductor part includes two regions provided along the first side surface of the finger gate electrode, and
a narrow region of the finger source electrode due to the opening and the two region of the conductor part do not overlap in plan view.

13. The transistor according to claim 10, wherein the finger part and the interconnect part are orthogonal.

14. The transistor according to claim 11, wherein the finger part and the interconnect part are orthogonal.

15. The transistor according to claim 10, wherein the finger source electrode is sandwiched between two finger gate electrodes, and includes at least two openings recessed from the two finger gate electrodes, respectively.

16. The transistor according to claim 11, wherein the finger source electrode is sandwiched between two finger gate electrodes, and includes at least two openings recessed from the two finger gate electrodes, respectively.

17. The transistor according to claim 12, wherein the finger source electrode is sandwiched between two finger gate electrodes, and includes at least two openings recessed from the two finger gate electrodes, respectively.

18. The transistor according to claim 10, wherein the spacing between a center of the finger gate electrode and the side surface of the finger part facing the finger drain electrode is not more than 1 μm.

19. The transistor according to claim 10, wherein
the multilayer body includes an electron supply layer made of AlGaN and a channel layer made of GaN, and
the channel layer generates a two-dimensional electron gas in a region in contact with the electron supply layer.
